(19) United States
(12) Patent Application Publication
(10) Pub. No.: US 2008/0087406 A1
(43) Pub. Date: Apr. 17, 2008

(54) Cooling system and associated method for planar pulsating heat pipe

(75) Inventors: Julie F. Asfia, Huntington Beach, CA (US); Marianne E. Mata, Dana Point, CA (US); Chung-Lung Chen, Thousand Oaks, CA (US); Qingjun Cai, Thousand Oaks, CA (US); Bruce L. Drolen, Altadena, CA (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: The Boeing Company

(21) Appl. No.: 11/549,378

(22) Filed: Oct. 13, 2006

(51) Int. Cl. F28D 15/00; H05K 7/20

(52) U.S. Cl. 165/104.29; 165/104.33; 361/700

(57) ABSTRACT

A cooling assembly, system, and method are provided. The cooling assembly includes a plate comprising a plurality of channels defined in a surface of the plate and at least one pulsating heat pipe comprising tubing. At least a portion of the tubing is positioned within the channels, and the tubing is configured for carrying coolant therein.

### BACKGROUND OF THE INVENTION

1) Field of the Invention

Embodiments of the present invention relate to a cooling system and, more particularly, to a cooling system employing a pulsating heat pipe for cooling a fuel cell, digital signal processor, and the like.

2) Description of Related Art

A digital signal processor (“DSP”) is a special type of central processing unit that provides mathematical calculations for digital signal processing applications. In general, digital signal processing clarifies or standardizes the levels or states of a digital signal. A digital signal processing circuit is able to differentiate between human-made signals and noise. A DSP is typically employed to perform a specific task and is part of a larger host processor. DSPs may be used in communication satellites, sound cards, fax machines, modems, cellular phones, high-capacity hard disks, and digital TVs.

Moreover, DSPs may be mounted on a printed circuit board (“PCB”), which may have additional processors on the same PCB. Several PCBs are commonly mounted into a single chassis box. The heat generated by electronic devices carried by the PCB is dissipated by conduction to a metallic material (e.g., aluminum) or non-metallic material positioned between the PCBs. The heat is then sent to an external heat sink by conduction through the metallic material and taken away by either cool air circulating about the heat sink, a cold plate or heat pipes. Because of high thermal resistance in the heat transfer path, the waste heat load leads to a large temperature gradient (ΔT) between the electronic devices that are generating heat and the heat sink. This large ΔT may adversely affect the performance of the electronic devices. Consequently, a more effective heat transfer approach had to be developed to address these thermal problems.

One advanced heat transfer approach is pulsating heat pipe (PHP) technology. A PHP is made with a looped or unlooped meandering capillary tube that forms a closed circuit, as shown in FIG. 1. After partially filling a capillary tube that is maintained at a reduced pressure with liquid, the PHP reaches equilibrium by forming a plurality of liquid slugs separated by vapor bubbles, i.e., regions of liquid and saturated vapor. In operation, heat is introduced in an evaporating region and is withdrawn from a condensing region. At steady state, heat transfer is achieved by continuous oscillatory movements from the evaporating region to the condensing region, which is caused by instant pressure imbalance among different turns. Both phase change and sensible heat exchanges are considered to participate in the heat transfer.

Since the late 1990's, PHP operating characteristics and mechanisms have been studied extensively, and this technology has been applied to more and more fields. For instance, the PHP technology has been employed to provide avionics device cooling, which has provided a significant reduction in thermal resistance, and employs the systems disclosed in U.S. Pat. Nos. 4,921,041 and 5,697,428 to Akachi. In particular, and as shown in FIG. 2 of the present application, an avionics chassis box was disclosed to house printed circuit boards and to include a tunnel plate heat pipe within a wall of the chassis box. Another wall of the chassis box may be a cold plate connected to a condenser to output the heat that has been transferred to the heat pipe from the PCB's. By positioning the heat pipe within the wall, the thermal resistance is reduced and the heat transport capability is increased.

With the introduction of new and additional electronic devices that generate more heat in avionics and other systems, more waste heat is generated by the printed circuit boards. For instance, a new generation of electronic systems utilized in an avionics chassis may need to dissipate up to 1000 watts of total waste heat during operation. For example, each power supply module may generate and need to dissipate approximately 100 watts. The increasing heat dissipation requirements therefore cause a very large temperature gradient when traditional cooling solutions are utilized. Therefore, despite the above-mentioned improvements in avionics cooling including incorporating the PHP into the chassis box, additional improvements are desired that are capable of handling increasing amounts of waste heat.

Fuel cells provide similar issues with respect to removal of waste heat. Individual fuel cells may be integrated into a fuel cell stack, and there may be various types of fuel cells, such as alkaline (“AFC”), proton exchange membrane (“PEMFC”), solid oxide (“SOFC”), phosphoric acid (“PAFC”), or molten carbonate (“MCFC”). In general, fuel cells are electrochemical conversion devices that include an anode, cathode, and an electrolyte. For example, in a PEMFC, hydrogen gas (H₂) enters the fuel cell on the anode side and electrochemically reacts at the interface of the anode and proton exchange membrane electrolyte. When an electrical load is applied across the fuel cell, the H₂ molecule splits into two H⁺ ions and two electrons (e⁻). The electrons are conducted through the anode, where they make their way through the external circuit providing current and return to the cathode side of the fuel cell while the H⁺ ions are transported across the electrolyte. On the cathode side of the fuel cell, the hydrogen ions react with the oxygen atoms and electrons at the cathode electrolyte interface to form a water molecule (H₂O).

To increase the voltage generated, several individual fuel cells may be integrated into a fuel cell stack. Bipolar plates positioned between individual fuel cells can provide electrical conductivity from cell to cell as well as separating and directing the reactant flows. The chemical reaction within each fuel cell generates waste heat. Currently, in order to cool a PEMFC fuel cell stack, a cooling liquid such as deionized water can be actively pumped between the fuel cells, which can require additional hardware such as more bipolar plates and active coolant liquid control components. There is typically a single coolant loop for the fuel cell stack which is separated into many paths to cool each of the individual fuel cells. The hot coolant exiting the fuel cells in the stack is collected through a stack exit and is cooled using a heat sink. However, the thermal resistance between individual fuel cells within the stack to the heat sink of the fuel cell system, as well as the reaction time of the active cooling system to changes in heat loads, are in need of an improved power system thermal management. Moreover, the pumps provide moving parts that may not be as reliable as cooling systems having non-moving parts. Also, especially in PEMFC stacks, there is only a single coolant path to cool the cell, with no redundancy available in the system in the event of an active cooling system component failure.

It would therefore be advantageous to provide an improved cooling system for rapidly dissipating the increased amounts of waste heat generated by electrical systems and fuel cells. In this regard, it would be advantageous to provide a cooling system that provides a higher heat transfer capability and lower thermal resistance than conventional cooling systems. It would also be advantageous to provide a cooling system that offers a relatively simple construction, that can provide cooling redundancy and possible weight reduction, and that may be integrated with conventional electrical systems and fuel cells.

### BRIEF SUMMARY OF THE INVENTION

Embodiments of the present invention address the above needs and achieve other advantages by providing an improved cooling system that is capable of employing a planar pulsating heat pipe for cooling an electronic system or fuel cell stack. For example, the planar pulsating heat pipe may be positioned adjacent to a printed circuit board or individual fuel cell. Thus, the pulsating heat pipe may readily and effectively transfer heat away from the printed circuit board and fuel cell.

In one embodiment of the present invention, a cooling assembly is provided. The assembly includes a plate comprising a plurality of channels defined in a surface of the plate and at least one pulsating heat pipe comprising tubing. At least a portion of the tubing is positioned within the channels, and the tubing is configured for carrying coolant therein.

According to aspects of the cooling assembly, the channels are curved, and the tubing may comprise a portion of which is curved and a portion of which is non-curved, wherein the curved portion of the tubing is positioned within the curved channels. Each channel may define a plurality of radii, and the curved portion of the tubing may define a plurality of radii that substantially conforms to the plurality of radii of each channel. Further aspects of the cooling assembly provide a pulsating heat pipe including an evaporator and a condenser. The evaporator may be substantially larger in width than the condenser. Also, the plurality of channels may be arranged in a serpentine configuration within the plate. The assembly may include an adhesive applied to at least a portion of the multi-radii channels for securing the tubing therein.

An additional aspect of the present invention provides a cooling system. The system includes at least one heat source (e.g., printed circuit board or fuel cell) having opposed surfaces and a cooling assembly positioned adjacent to one of the surfaces of the heat source. The cooling assembly includes a plate comprising a plurality of channels defined in one of the surfaces of the plate. The cooling assembly also includes at least one pulsating heat pipe comprising tubing. At least a portion of the tubing is positioned within the plurality of the channels, and the tubing is configured for transferring heat from the at least one heat source.

Various modifications of the cooling system provide a pulsating heat pipe having an evaporator and a condenser. Moreover, the system may also include a heat sink thermally coupled to the condenser of the pulsating heat pipe. The evaporator of the pulsating heat pipe may be positioned adjacent to the at least one heat source. Each cooling assembly may be positioned between and adjacent to a pair of heat sources. Furthermore, at least a portion of each channel may be curved, and the tubing may have a portion of which is curved and a portion of which is non-curved, wherein the curved portion of the tubing is positioned within the curved portion of the channels such that the non-curved portion is substantially coplanar to at least a portion of the surface of the plate. In addition, the curved portion of the channel may include segments defining a plurality of radii, and the curved portion of the tubing may define a plurality of radii that substantially conforms to the plurality of radii defined by each curved channel.

Embodiments of the present invention also provide a method for manufacturing a cooling apparatus for cooling at least one heat source. The method includes defining a plurality of channels within a surface of a plate, and embedding at least a portion of at least one pulsating heat pipe comprising tubing within the channels such that a portion of the tubing conforms to the channels. The embedding step may include embedding the tubing such that a portion of the tubing is substantially coplanar to the surface of the plate. The defining step may include defining a plurality of curved channels within the plate, and the embedding step may include compressing the tubing such that a portion of the tubing defines a curved portion that conforms to the curved channels.

An additional embodiment of the present invention provides an additional cooling assembly. The cooling assembly a pulsating heat pipe comprising tubing, wherein at least a portion of the tubing comprises a planar surface, and wherein the tubing is configured for carrying coolant therein. The assembly further includes a first plate secured to the planar surface of the tubing. According to one aspect of the assembly, the tubing comprises a pair of opposing planar surfaces, wherein the first plate is positioned adjacent to one of the pair of opposing planar surfaces. In addition, a second plate may be positioned adjacent to one of the pair of opposing surfaces that is opposite the planar surface positioned adjacent to the first plate.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is cross-sectional view of a pulsating heat pipe, according to one conventional technique;

FIG. 2 is a perspective view of an avionics cooling system having a pulsating heat pipe positioned within a wall of a chassis box according to one prior art technique;

FIG. 4 is a perspective view of a cooling system according to one embodiment of the present invention;

FIG. 5 is a plan view of a cooling system according to an embodiment of the present invention;

FIG. 6 is a cross-sectional view of a portion of a cooling apparatus according to an embodiment of the present invention;

FIG. 7A is a cross-sectional view of a cooling apparatus according to another embodiment of the present invention;

FIG. 7B is a cross-sectional view of a cooling apparatus according to another embodiment of the present invention;

FIG. 8A is a cross-sectional view of a cooling apparatus according to an embodiment of the present invention;

FIG. 8A is a cross-sectional view of a cooling apparatus according to one embodiment of the present invention;

FIG. 9 is a cross-sectional view of a cooling apparatus according to an additional embodiment of the present invention; and

FIG. 10 is a graph depicting exemplary test results for a cooling system according to an embodiment of the present invention.

### DETAILED DESCRIPTION OF THE INVENTION

The present invention now will be described more fully hereinafter with reference to the accompanying drawings, in which some, but not all embodiments of the invention are shown. Indeed, this invention may be embodied in many different forms and should not be construed as limited to the embodiments set forth herein; rather, these embodiments are provided so that this disclosure will satisfy applicable legal requirements. Like numbers refer to like elements throughout.

Referring now to the drawings and, in particular to FIG. 3 there is shown a cooling system 10, according to one embodiment of the present invention. The cooling system 10 generally includes a plurality of heat sources 12 and a plurality of planar pulsating heat pipes (“PPHP”) 14. The cooling system 10 may be integrated with a fuel cell or printed circuit board (“PCB”). At least a portion of each PPHP 14 is positioned adjacent to a respective heat source 12 and, more typically, between a pair of heat sources. The remaining portion of the PHP 14 may be thermally coupled to a heat sink.

The cooling system 10 may be used with a variety of fuel cells, such as alkaline, proton exchange membrane, solid oxide, phosphoric acid, or molten carbonate. In addition, although a fuel cell stack is shown, it is understood that the cooling system 10 may be a single fuel cell. Similarly, the cooling system 10 may be utilized with one or more printed circuit boards (“PCBs”) including a variety of electrical components, such as a digital signal processor (“DSP”).

Furthermore, although the cooling system 10 may be referred to herein as being used with a fuel cell or PCB, it is understood that the cooling system is applicable to a variety of technologies that incorporate PPHP's 14 for cooling a variety of heat sources 12. For instance, the cooling system 10 is applicable to any number of industries that may incorporate one or more heat sources 12, such as a chassis box having electrical components contained therein. For instance, the electrical components could be various computer and controller equipment or other electrical components that are supported by a PCB.

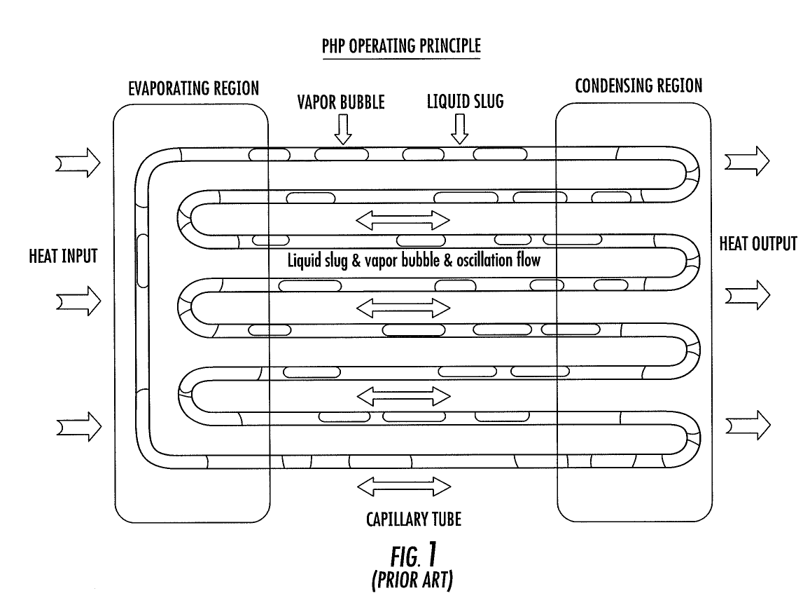

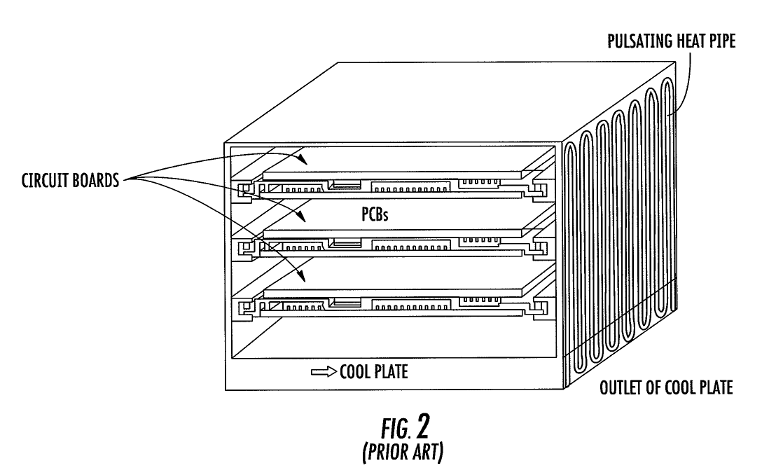

The chemical reaction within the fuel cell and electrical components integrated with the PCB, when in operation, act as heat sources that generate waste heat. The operating temperature of the heat sources 12 may vary, such as up to about 1000° C., while the heat load generated by the heat sources may also vary, such as up to about 400 watts. For heat sources generating a heat load greater than 400 watts, multiple PPHP's 14 may be used. To remove this waste heat and avoid any degradation of the performance of the fuel cell or PCB, a PPHP 14 is positioned along a major surface of the heat source 12. The PPHP 14 utilizes a PHP 18, as known to those skilled in the art, which could be any suitable PHP (see FIG. 1). Therefore, the PHP 18 includes a working fluid, such as water, acetone, or ethanol, that normally separates into different segments of liquid slugs that are spaced apart and separated by vapor bubbles within the PHP. The PHP 18 typically includes a serpentine or meandering tube of capillary dimensions and many U-turns. In addition, the PHP 18 generally comprises an evaporator 20 and a condenser 22, where heat received at the evaporator causes the liquid slugs and vapor bubbles to oscillate due to pressure pulsations created by the absorbed heat. As such, the pressure pulsations force the liquid slugs and vapor bubbles to move between the evaporator 20 and the condenser 22. As heat is applied to the PHP 18 in the evaporator 20 such as by the transfer of heat generated by the fuel cell or electronics (PCB), at least some of the liquid is vaporized in the evaporator. Upon reaching the condenser 22, in which the condenser region is generally cooler than the vapor arriving from the evaporator 20, at least some of the vapor condenses into liquid. The volume expansion due to the vaporization and contraction due to the condensation is one cause of the oscillating motion of the working fluid that sends vapor to the condenser 22 and returns liquid to the evaporator 20. At sufficiently high heat flux, nucleate boiling can occur in the liquid phase causing even more rapid oscillation of the liquid and vapor portions within the PHP. The oscillatory motion of the liquid slugs and vapor bubbles is self-sustaining as long as the heating and cooling conditions are maintained. Therefore, the PHP 18 is self-sufficient, driven by the heat load it is designed to reject, and does not require any external mechanical devices (e.g., pumps) or energy to operate.

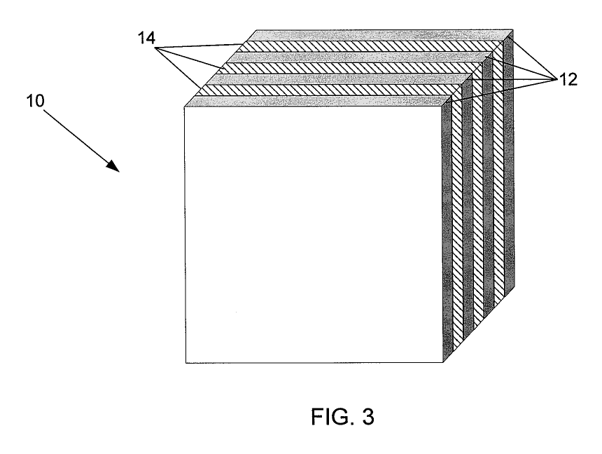

The PHP 18 should not be limited to any particular configuration, as the PHP could be any number of sizes and configurations in additional embodiments of the present invention. For instance, the PHP 18 could be various dimensions, the tube could have various diameters and configurations, the evaporator 20 and condenser 22 could have various widths and numbers of turns, and the evaporator may or may not have a wick structure. For instance, the condenser may be less than ½ of an inch or 4 mm in width in order to accommodate existing fuel cell and PCB configurations. Moreover, FIG. 4 illustrates an exemplary PHP 18, where the tubing 27 could have 5 turns and 10 pipes (see FIG. 4), and the PHP could be approximately 9-30 cm in width. According to one embodiment, for transferring about 400 watts of heat load, the PHP 18 may have about 12 turns. Moreover, the quantity of working fluid (i.e., filling ratio), types and properties of the working fluid, and tube material may be modified to generate different heat transfer results. For example, the filling ratio could be approximately 30-75%, while the tube could be a copper material with approximately 3-4 mm in outer diameter and 1-2 mm in inner diameter. In addition, the PHP 18 could be open or closed-loop, and oriented in various positions. Thus, the PHP 18 could be a closed loop, where the tube is joined end-to-end, such as that shown in FIG. 4.

According to advantageous embodiments of the present invention, the PPHP 14 extends adjacent to a major surface of a heat source 12 (or a pair of heat sources, as shown in FIG. 3). As a result of this construction, the evaporator 20 region of the PHP 18 is generally formed by that portion of the PHP that extends adjacent to the heat source 12 and absorbs heat therefrom, while the condenser 22 region is typically not adjacent to the heat source, such as being positioned adjacent to a heat sink. In particular, where each of the heat sources 12 includes opposing surfaces and a thickness extending therebetween, the evaporator 20 is typically positioned along and adjacent to one of the opposing major surfaces of each heat source 12, as shown in FIG. 4. Therefore, the PPHP 14 is not limited to localized cooling of the heat source 12 in areas proximate to the generation of waste heat. As the heat sources 12 operate, the evaporator 20 is capable of removing or otherwise transferring heat from the heat sources. The condenser 22 of the PHP 14 shown in FIG. 4 is not positioned adjacent to the heat source 12 such that the portion of the PHP 18 that extends beyond the heat source typically forms the condenser. In addition, a condenser 22 may be located on one side of the evaporator 20, or the condenser may be located on opposite sides of the evaporator and may be different sizes. The PHP 18 of this embodiment is substantially planar such that the evaporator 20 and condenser 22 of the PHP are collinear. Waste heat removed by the evaporator 20 of the PHP 14 and transferred to the condenser 22 of the PHP, may be further transferred to a heat sink. Thus, the cooling system 10 may employ a heat sink, such as cooling with air, liquid, fan, cold plate, loop heat pipe, or any other heat sink known to those skilled in the art.

In regards to the aforementioned cooling system 10, the evaporator 20 of the PHP 14 may be positioned adjacent to a pair of heat sources 12 or attached to a heat source with an adhesive, solder, fastener, or similar technique that secures the evaporator directly to the surface of respective heat sources. Furthermore, a high thermal conductivity epoxy may be used to attach each PPHP 14 to the heat source 12. Also, the condenser 22 could be attached with an adhesive, fasteners, clamps, or similar fastening technique directly to an inner surface of the wall of the fuel cell stack components or fixture, PCB, or chassis box. For example, the ends of the condenser 22 could be secured to wedge locks for securing the PPHP 14 within a chassis box.

It is understood that the cooling system 10 illustrated in FIGS. 3 and 4 is not meant to be limiting, as the cooling system may comprise various configurations in alternative embodiments of the present invention. For instance, the arrangement of the heat sources 12 and PPHP 14 may be arranged in, and is unaffected by, different orientations. Thus, the cooling system 10 is capable of cooling the heat sources 12 irrespective of orientation, which is useful for applications, such as avionics, where orientation and gravitational forces may be constantly changing. Furthermore, although the PPHP 14 shown in FIGS. 3 and 4 includes an evaporator 20 that is collinear to the condenser 22, the PHP 18 may be configured in any suitable manner for accommodating various cooling systems, such as where the condenser is arranged perpendicular to the evaporator. Thus, the plate 24 need not be planar and could be various configurations in order to configure the PPHP 14 for cooling a particular heat source(s). In addition, there may be any number of PPHP's 14 for accommodating various electronic applications and achieving desired cooling properties. For example, FIG. 3 demonstrates that there may be three PPHP's 12 and four heat sources 12. Similarly, a PPHP 14 may be positioned between individual heat sources 12 as shown in FIG. 3, or the PPHP may be positioned between every two, three, etc. heat sources depending on the application and desired cooling properties. Moreover, each plate 24 may include one or more PHPs 18 integrated therein, rather than a single PHP as shown in FIG. 4.

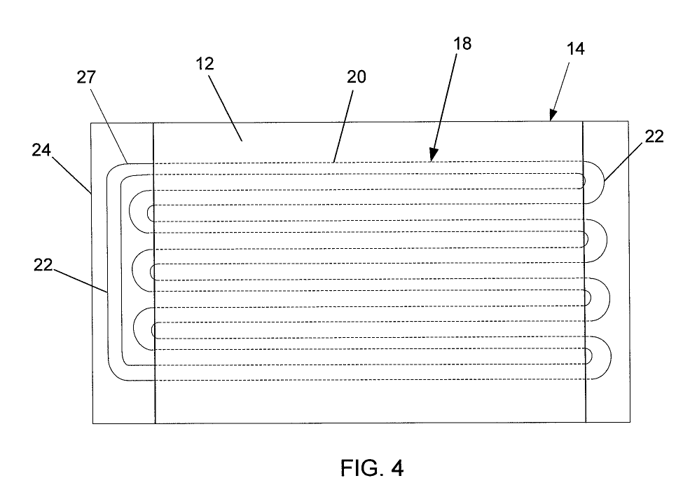

Each PPHP 14 includes a plate 24 and a PHP 18 embedded therein. In particular and as shown in more detail in FIG. 5, the plate 24 includes a plurality of channels 26 that are each capable of accommodating tubing 27 of the PHP 18. Each groove 26 includes segments defining a plurality of radii, where a pair of segments have a first radius 28 and extend from an outer surface of the plate 24, and another segment having a second radius 30 extending between the segments having the first radius within the plate. Moreover, the tubing 27 includes a planar portion 32 and a pair of tubular portions having a first radius 34 and another tubular portion having a second radius 36 and extending between the pair of tubular portions having the first radius. Thus, the first radii 34 of the tubing 27 are configured to conform to the first radii 30 of the plate 24, while the second radius 36 of the tubing is configured to conform to the second radius 30 of the plate. In general, the radii 34 and 36 of the tubular portions are smaller or equal to the radii 28 and 30 of the segments in the plate 24. Each of the first radii 28 and 34 are smaller than the second radii 30 and 36.

The plate 24 is typically a thermally conductive material, such as aluminum. The first 28 and second 30 radii of the plate 24 may be defined using various machining processes, such as milling, cutting, etching, and the like, or molded with channels 26 defined therein. Moreover, the tubing 27 is also typically a thermally conductive material, such as copper, and includes an opening 38 for carrying coolant therethrough. In order to form the tubing 27 into the illustrated configuration, a tubing of substantially circular cross section may be positioned within the channels 26 and compressed to define the first 34 and second 36 radii and planar portion 32. The tubing 27 could also be preformed or molded prior to positioning the tubing within the channels 26. The tubing 27 may be press fit within the channels 26, or an adhesive may be applied to the tubing or channels to further secure the tubing within the channels. The tubing 27 is positioned within the channels 26 such that the planar portion 32 of the tubing is not covered but, rather, extends generally co-planar to the outer surface of the plate 24. The PHP 18 or plate 24 may be positioned adjacent to the heat source 12. Moreover, the tubing 27 is typically in intimate contact along the channels 26 in order to have complete contact for increasing thermal conduction. Thus, although FIG. 5 shows gaps between the tubing 27 and channels 26, the tubing my substantially follow the contour of the channels, or a filler bonding material could be used to fill in the gaps between the tubing and channels.

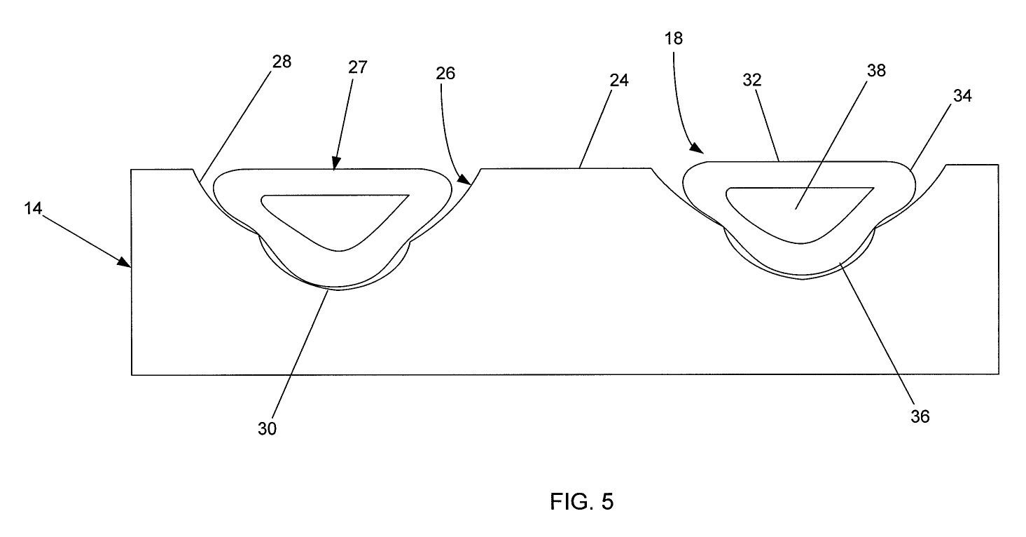

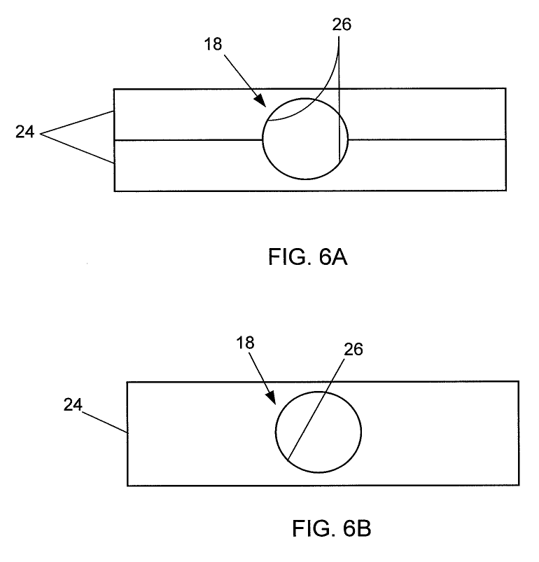

It is understood that the illustrated PPHP 14 is not meant to be limiting. In this regard and according to another embodiment of the present invention, although the tubing 27 is shown as being positioned within the channels 26, the channels could also be defined in the plate 24 such that tubing is unnecessary. For example, the channels 26 could be defined in a first plate and/or a second plate, and the plates secured to one another to effectively define the opening 38 of tubing of a PHP 18 for carrying coolant therein. As shown in FIG. 6A, a semi-circular channel 26 is defined in respective plates 24, and the plates are then joined together. For example, the plates 25 could be bonded using adhesives, diffusion bonding (e.g., hot isostatic press), welding, and the like in order to form a fluid-tight seal between the plates. Or, a circular channel 26 could be defined in a single plate 24, as shown in FIG. 6B. For instance, the plate 24 shown in FIG. 6B could be a bi-polar plate in a fuel cell stack. FIG. 7A depicts a further variation wherein each channel 26 is defined in respective plates and includes an angular segment 40 extending from each end of a curved segment 42. In a similar configuration, FIG. 7B illustrates a first plate 24 having angular 40 and curved 42 segments defined therein, and a second plate having no channel is secured to the first plate. The angular 40 and curved 42 segments of the channels shown in FIGS. 7A-7B facilitate fluid flow within the channels.

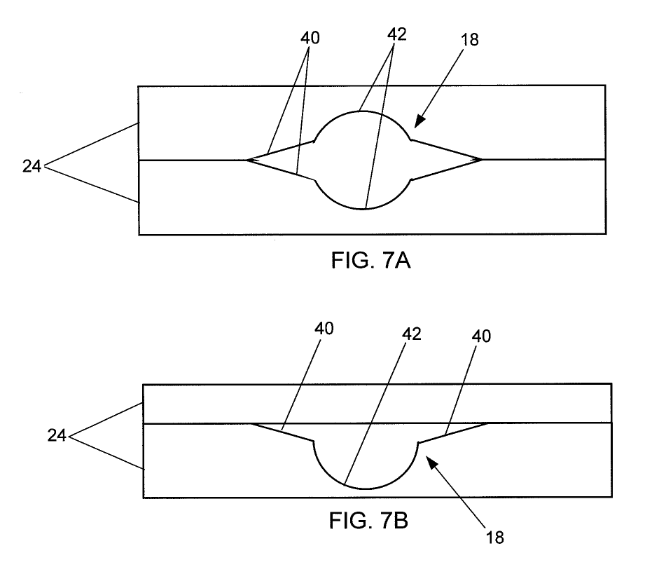

According to another embodiment of the present invention, FIG. 8 shows that the PHP 18 may be positioned between a pair of plates 24. Thus, the tubing 27 may be compressed between the plates 24 to form opposing planar surfaces that are adjacent to each plate. The planar surfaces of the tubing 27 facilitate attachment and thermal conductivity with the plates 24. The tubing 27 may be secured to the plates using various techniques (e.g., welding, adhesives, etc.). By eliminating portions of the plates 24 between the tubing 27, the PPHP 14 may be lighter than a PPHP having channels formed directly in the plate.

Moreover, although the channels 26 and tubing 27 of FIG. 5 each includes a pair of first radii and a second radii extending therebetween, it is understood that the channels 26 and tubing 27 may include one or more radii or curved portions, or the channels and tubing could be various cross sections (e.g., rectangular, square, hemi-cylindrical, or triangular). Although the outer surface of the plate 24 shown in FIG. 5 is uncovered, a top plate may be secured to the outer surface of the plate to cover the tubing 27 that is positioned within the channels 26. In addition, the first and second radii of each of the channels 26 and tubing 27 could be various sizes; for example, the first radii of the channels may be about 4.76 mm and the second radius of the channels may be about 2.15 mm according to one embodiment of the present invention. The plate 24 and tubing 27 may be various thermally conductive materials and various sizes and configurations depending on the particular cooling application. For example, the plate 24 could be about 380 mm×305 mm and about 4 mm in thickness.

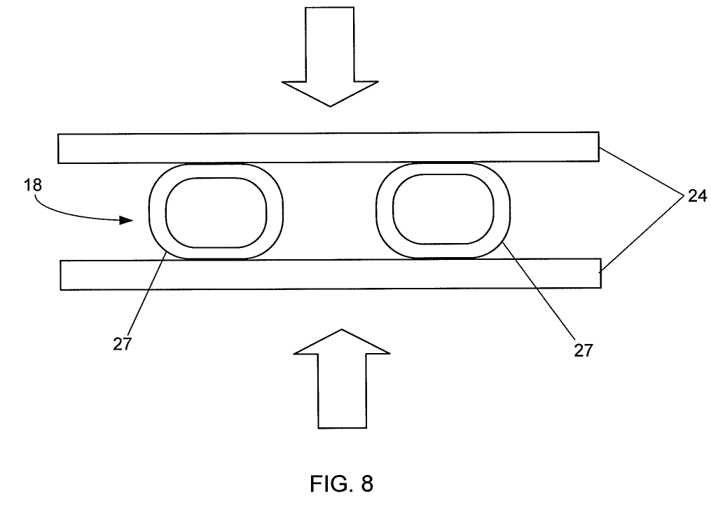

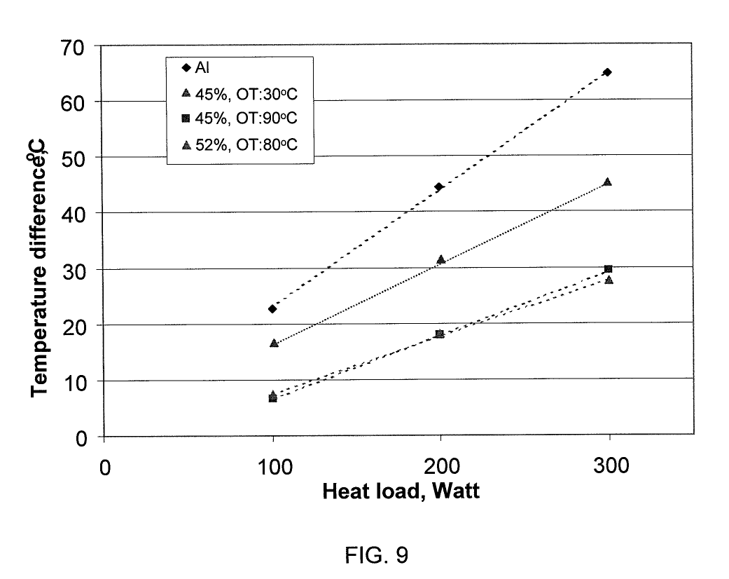

Preliminary experimental results have demonstrated that the cooling system 10 of one embodiment of the present invention is more effective than traditional cooling techniques. FIG. 9 illustrates a graph of heat load versus temperature difference, where heat load corresponds to power applied through the heat sources 12, and temperature difference corresponds to the temperature gradient between the heat sources and the heat sink. For example, FIG. 9 shows that for a heat load of 100 watts and a fill ratio of 52% for an operating temperature (“OT”) of 80° C., the temperature difference was about 7° C. In contrast, at the same heat load of 100 watts the temperature difference for an aluminum sheet of comparable thickness to transfer heat to a heat sink was about 23° C. The temperature difference for the PPHP 14 for each of the three fill ratios/operating temperatures was lower than using an aluminum plate with no PHP. Thus, the heat transfer performance of each of the working fluids in the PPHP 14 is better than simply using an aluminum sheet to transfer heat to the heat sink.

Embodiments of the present invention therefore provide a cooling system 10 capable of cooling one or more heat sources 12, such as a fuel cell or PCB. Moreover, the PPHP 14 may be configured to be integrated with existing fuel cell and chassis boxes. The cooling system 10 is adaptable to a variety of technologies, including avionics, and may be customized for various cooling needs. The cooling system 10 of one advantageous embodiment that employs a PPHP 14 may take up a minimal amount of space by positioning the evaporator 20 between pairs of heat sources 12, and positioning the condenser 22 within, or adjacent to, a heat sink. In addition, PHP's 18 are generally known to have a lower manufacturing cost, have a simple and lightweight internal structure, and have a higher heat transfer capability than conventional avionics cooling techniques. Thus, embodiments of the present invention may provide a cooling system 10 capable of reducing the temperature gradient between the heat sources 12 and the heat sink, as well as reducing the thermal resistance between the heat sources 12 and PHP 18. Because of the improved heat transfer characteristics, the cooling system 10 may be better capable of handling the increasing demands of new fuel cells and electronic devices in avionics and other technologies. As such, the reliability and performance of fuel cells and electronics may be improved due to the reduction of temperature of the heat sources 12.

Many modifications and other embodiments of the invention set forth herein will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A cooling assembly comprising:
a plate comprising a plurality of channels defined in a surface of the plate; and
at least one pulsating heat pipe comprising tubing, wherein at least a portion of the tubing is positioned within the channels, and wherein the tubing is configured for carrying coolant therein.

2. The assembly according to claim 1, wherein the plurality of channels are curved.

3. The assembly according to claim 2, wherein the tubing comprises a portion of which is curved and a portion of which is non-curved, and wherein the curved portion of the tubing is positioned within the curved channels.

4. The assembly according to claim 3, wherein each curved channel defines a plurality of radii, and wherein the curved portion of the tubing defines a plurality of radii that substantially conforms to the plurality of radii of each curved channel.

5. The assembly according to claim 1, wherein the pulsating heat pipe comprises an evaporator and a condenser.

6. The assembly according to claim 5, wherein the evaporator is substantially larger in width than the condenser.

7. The assembly according to claim 1, wherein the plurality of channels are arranged in a serpentine configuration within the plate.

8. The assembly according to claim 1, further comprising an adhesive applied to at least a portion of the channels for securing the tubing therein.

9. A cooling system comprising:
at least one heat source having opposed surfaces; and
a cooling assembly positioned adjacent to one of the surfaces of the heat source, the cooling assembly comprising:
a plate comprising a plurality of channels defined in a surface of the plate; and
at least one pulsating heat pipe comprising tubing, wherein at least a portion of the tubing is positioned within the channels, and wherein the tubing is configured for transferring heat from the at least one heat source.

10. The system according to claim 9, wherein the pulsating heat pipe comprises an evaporator and a condenser.

11. The system according to claim 10, further comprising a heat sink thermally coupled to the condenser of the pulsating heat pipe.

12. The system according to claim 10, wherein the evaporator of the pulsating heat pipe is positioned adjacent to the at least one heat source.

13. The system according to claim 9, wherein the at least one heat source comprises a printed circuit board.

14. The system according to claim 9, wherein the at least one heat source comprises a fuel cell.

15. The system according to claim 9, wherein each cooling assembly is positioned between and adjacent to a pair of heat sources.

16. The system according to claim 9, wherein at least a portion of each channel is curved.

17. The system according to claim 16, wherein the tubing comprises a portion of which is curved and a portion of which is non-curved, and wherein the curved portion of the tubing is positioned within the curved portion of the channels such that the non-curved portion is substantially coplanar to at least a portion of the surface of the plate.

18. The system according to claim 17, wherein the curved portion of the tubing defines a plurality of radii that substantially conforms to a plurality of radii defined by each curved channel.

19. A method for manufacturing a cooling apparatus for cooling at least one heat source, the method comprising:
defining a plurality of channels within a surface of a plate; and
embedding at least a portion of at least one pulsating heat pipe comprising tubing within the channels such that a portion of the tubing conforms to the channels.

20. The method according to claim 19, wherein embedding comprises embedding the tubing such that a portion of the tubing is substantially coplanar to at least a portion of the surface of the plate.

21. The method according to claim 19, wherein defining comprises defining a plurality of curved channels within the plate.

22. The method according to claim 21, wherein embedding comprises compressing the tubing such that a portion of the tubing defines a curved portion that conforms to the curved channels.

23. A cooling assembly comprising:
a pulsating heat pipe comprising tubing, wherein at least a portion of the tubing comprises a planar surface, and wherein the tubing is configured for carrying coolant therein; and
a first plate secured to the planar surface of the tubing.

24. The assembly according to claim 23, wherein the tubing comprises a pair of opposing planar surfaces, and wherein the first plate is positioned adjacent to one of the pair of opposing planar surfaces.

25. The assembly according to claim 24, further comprising a second plate positioned adjacent to one of the pair of opposing surfaces that is opposite the planar surface positioned adjacent to the first plate.
